(19) United States
(12) Patent Application Publication
(10) Pub. No.: US 2004/0257775 A1
(43) Pub. Date: Dec. 23, 2004

(54) Data input device having a plurality of inter-connected components

(75) Inventor: Brian E. Jones, Hampshire (GB)

Correspondence Address: IBM CORPORATION, PO BOX 12195, DEPT 9CCA, BLDG 002, RESEARCH TRIANGLE PARK, NC, 27709, US

(73) Assignee: International Business Machines Corporation, Armonk, NY

(21) Appl. No.: 10/741,369

(22) Filed: Dec. 19, 2003

(30) Foreign Application Priority Data
Jun. 21, 2003 (GB) 0314589.3

(51) Int. Cl. H05K 7/16

(52) U.S. Cl. 361/725

(57) ABSTRACT

A data input device comprising a plurality of inter-connected components. Each of the plurality of components comprises a plurality of faces and at least one of the plurality of faces represents at least one data input (e.g. a character, a function data input, a control data input). The data input device also comprises a mechanism which enables selection of the at least one data input.

### FIELD AND BACKGROUND OF INVENTION

The present invention relates to data input devices.

One problem associated with using pervasive devices (e.g. Personal Digital Assistant (PDAs), mobile telephones etc.) is providing a reliable and user-friendly method for data input. With reference to keyboards (i.e. a data input device), a keyboard suitable for personal computers is not appropriate in the field of pervasive devices, because full size keyboards are not practical and compact.

There are numerous mechanisms available today that attempt to solve this problem. A first example is a scaled down (e.g. to pocket size) “QWERTY” keyboard. These keyboards are typically external to the pervasive device, but can also be incorporated into the pervasive device. A problem associated with this solution is that the keys are small and crowded, making typing difficult. Also, the keyboard is not very portable. A scaled down keyboard may also be foldable and although this allows portability, the added effort required to unfold and attach the keyboard to the pervasive device can be frustrating.

A second example is a virtual “QWERTY” keypad, which appears on a touch-sensitive screen. Key selection can occur via a pointing device (e.g. a stylus). A problem associated with this solution is that the keypad takes up screen real estate, often overwriting running applications. Furthermore, the virtual keys are small and an external device is need for selection of keys. This hinders fast and reliable data input.

A third example is a numeric keypad, wherein a single key represents a plurality (typically three) of alphabetic characters, as well as numeric characters and punctuation characters. This type of keypad is often available on mobile telephones. Although the keypad is compact, a disadvantage is that multiple key presses may be required when selecting a character and this causes delay and is error prone. This type of keypad is often combined with word prediction, in order to speed up the data input process. However, the process may still require multiple key presses.

A fourth example is a handwriting recognition mechanism. One mechanism recognizes natural handwriting and another recognizes handwriting that needs to be inputted in a specific way (e.g. Palm Graffiti (Palm is a trademark and Graffiti is a registered trademark of Palm, Inc)). A problem associated with the former is that natural handwriting recognition is often unreliable. A problem associated with the latter is that a degree of learning is required. Furthermore, both mechanisms require an external pointing device (e.g. a stylus) and are slow methods for data input.

A fifth example is a mechanism that uses voice as a data input mechanism. Although no external devices are required, voice data input is often unreliable (especially in noisy environments). Furthermore, this mechanism is not appropriate in certain situations (e.g. input of confidential data). Additionally, because of the processing power required for such a mechanism, voice data input is often not available for pervasive devices.

A sixth example is a chorded keyboard, wherein each character is represented by a combination of keys rather than a single key e.g. 63 characters can be implemented using 6 physical keys. This solution is therefore compact, however, a chorded keyboard is difficult to learn and use and has therefore not become a popular option.

The prior art systems inhibit fast and reliable data input and also require considerable concentrated focus from a user when inputting data. There is a need for a data input mechanism that allows fast and reliable data input, requires a moderate level of concentrated focus, is compact, is portable and is easy to use.

### SUMMARY OF THE INVENTION

Accordingly, the present invention provides a data input device comprising: a plurality of inter-connected components, wherein each of the plurality of components comprises a plurality of faces and wherein at least one of the plurality of faces represents at least one data input; and a mechanism which enables selection of the at least one data input. As described more fully hereinafter, the mechanism employed may vary among several enablements.

In one embodiment, at least one of the plurality of faces has a surface feature such as an associated protrusion or a recess and the mechaism enabling selection comprises a detector which detects depression of the protrusion or the recess. Consequently, the selected data input is output.

In another embodiment, each of the plurality of components is rotatable about a selection position and the mechanism which enables selection comprises a detector which detects when the at least one of the plurality of faces is in the selection position. Preferably, the data input device comprises an orientation element representing an indication of orientation and the orientation of the element represents a selection position. In a preferred embodiment, the data input device provides tactile feedback to a user when the at least one of the plurality of faces is in the selection position. Preferably, a time threshold is associated with rotation. For example, in the case of a component being rotated twice whereby a first face then a second face is brought into the selection position, if the second rotation occurs within a time threshold (e.g. one second), only the data input represented by the second face is output. However, if the time taken to execute the second rotation exceeds the time threshold (e.g. more than one second), firstly the data input represented by the first face is output and then the data input represented by the second face is output.

Preferably, at least one of the plurality of faces represents one or more modes of operation (e.g. alphabetic shift mode, punctuation shift mode). In a preferred embodiment, the data input device comprises an associated display, which displays the results of data input selection.

In one embodiment, at least one of the plurality of components differs in size to the others of the plurality of components. In another embodiment, at least one of the plurality of components differs in tactile properties to the others of the plurality of components. Advantageously, this allows a user to distinguish between components. In yet another embodiment, at least one of the plurality of faces differs in tactile properties to the others of the plurality of faces. Advantageously, this allows a user to distinguish between faces.

Preferably, a first component is inter-connected to a second component via a spacing element. In a preferred embodiment, the data input device comprises means for communicating with an entity e.g. a pervasive device.

### BRIEF DESCRIPTION OF DRAWINGS

Some of the purposes of the invention having been stated, others will appear as the description proceeds, when taken in connection with the accompanying drawings, in which:

FIG. 1 shows a representation of a component of a data input device in accordance with the present invention;

FIG. 2 shows a representation of the component of FIG. 1 connected to another component;

FIG. 3 shows one embodiment for selection of a data input;

FIG. 4 shows another embodiment for selection of a data input; and

FIG. 5 shows the data input device after data input selection using the embodiment of FIG. 4.

### DETAILED DESCRIPTION OF INVENTION

While the present invention will be described more fully hereinafter with reference to the accompanying drawings, in which a preferred embodiment of the present invention is shown, it is to be understood at the outset of the description which follows that persons of skill in the appropriate arts may modify the invention here described while still achieving the favorable results of the invention. Accordingly, the description which follows is to be understood as being a broad, teaching disclosure directed to persons of skill in the appropriate arts, and not as limiting upon the present invention.

Generally there is provided a data input device suitable for use with another device (e.g. a PDA, a mobile telephone), described herein as an entity.

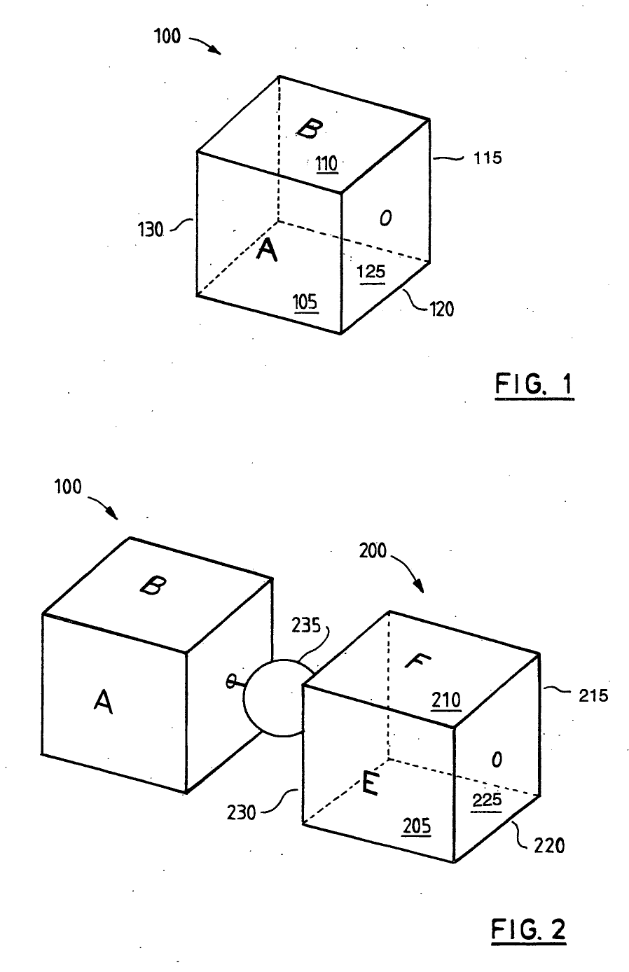

With reference to FIG. 1, there is shown a representation of a preferred embodiment of a component (100) of a data input device according to the present invention. In one embodiment, the data input device is a keyboard and the component is a key. In FIG. 1, there is shown a cube-shaped, regular-shaped component (100), comprising six faces. It should be understood that the component can also have any other shape and can be irregular in shape.

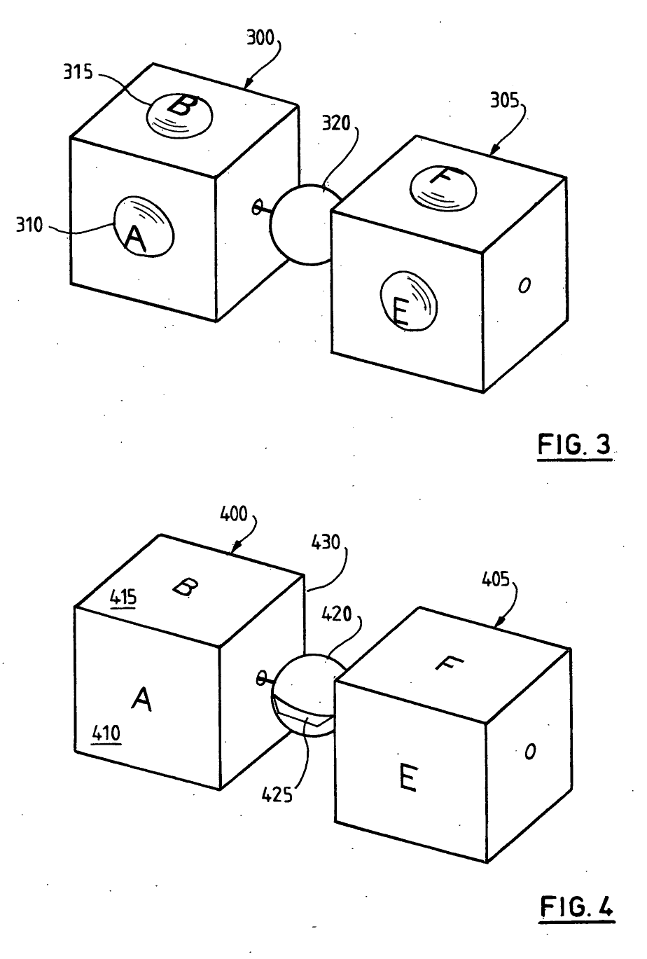

In the preferred embodiment, as shown in FIG. 1, each of a proportion of the faces (termed herein as “available faces”) 105, 110,115 and 120 represents a data input (e.g. alphabetic character, numeric character, punctuation function etc.). Faces 125 and 130 are not used to represent data inputs (termed herein as uunavailable facesn) and as can be seen in FIG. 2, this is because the applicant envisages the data input device as a plurality of components inter-connected to each other. Face 125 is therefore required to enable a connection to a second component (200), preferably, via a spacing element (235). The second component (200) also comprises six faces, wherein each of a proportion of the faces represents a data input (i.e. 205, 210, 215, 220) and the remaining faces enable connection to other components (i.e. 225, 230). Face 130 can be connected to a third component (not shown). In an alternative embodiment, all of the faces of a component represent a data input.

Therefore it can be seen that positioning two components (100, 200) in an adjacent manner, provides for representation of eight data inputs. In this way, the use of three components provides the functionality for standard numeric characters (requiring ten data inputs) and the use of nine components provides the functionality for standard alphanumeric characters (requiring thirty six data inputs).

Preferably, a further component is provided in order to function as a “modifier” component (e.g. providing alphabetic shift (i.e. upper case/lower case) and punctuation shift (e.g. &, *)). The further two faces of the modifier component can be used for other data inputs e.g. for the most common punctuation characters (e.g. the space function and the carriage return function), or for a function data input (e.g. the “escape” function, “F1” etc.) mode, or for a control data input (e.g. “insert”, “delete” etc.) mode.

In one embodiment, more than one data input can be represented by a face e.g. a face representing “a” also represents “@” in the punctuation shift mode. This allows the required number of components to be kept down to minimum.

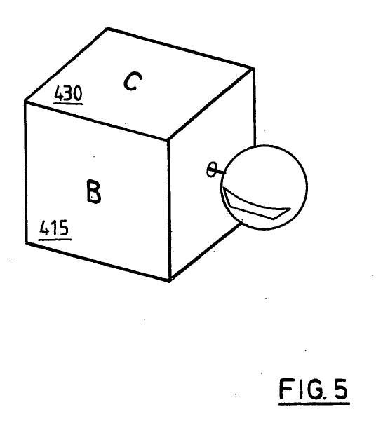

Two embodiments detailing selection of data inputs will now be described with reference to FIG. 3, FIG. 4 and FIG. 5. In a first embodiment, FIG. 3 shows two components (300, 305) separated by a spacing element (320) wherein each component comprises six faces. Referring to the first component (300), the available faces each have a surface feature. The surface feature may comprise an associated protrusion (or a recess) (only 310 and 315 are shown). Each surface feature represents a data input and data input selection occurs by a user pressing on the surface feature. The data input device preferably comprises circuitry or some other appropriate element detecting the depression of the protrusion, after which, the selected data input is output.

In a second embodiment, FIG. 4 shows two components (400, 405) separated by a spacing element (420) wherein each component comprises six faces. There is also shown an orientation element (425) located on the spacing element (420) representing an indication of orientation. The orientation of the element (425) represents a selection position. Each component is rotatable about the horizontal axis (i.e. the selection position).

Referring to the first component (400), each available face (410, 415 and 430) represents a data input. In this example, in order to select the letter “B” (represented by face 415), the component (400) is rotated through a 90 degree angle so that face 415 is brought into the selection position as shown in FIG. 5. Referring again to FIG. 4, in another example, in order to select the letter “A” (represented by face 410), since the face (410) is already in the selection position, the component (400) is rotated (e.g. through a 90 degree angle) off the selection position and then rotated (e.g. through a 90 degree angle) back to the selection position. Referring again to FIG. 4, in another example, in order to select the letter “C” (represented by face 430), the component (400) is rotated through a first 90 degree angle so that face 415 is brought into the selection position and then through a second 90 degree angle so that face 430 is brought into the selection position. Preferably, so that the letter “B” is not registered when face 415 is brought into the selection position, the data input device comprises a time threshold associated with rotation. For example, if the second rotation occurs within one second of the first, only the letter “C” is selected and output, however, if the second rotation occurs more than one second after the first, firstly the letter “B” is output and then the letter “C” is output.

Preferably, in addition to the orientation element (425), each component is provided with a detent that provides tactile feedback to the user when a face reaches the selection position (i.e. a detent every 90 degrees of rotation).

In a preferred embodiment, the data input device has an associated display in order to provide visual feedback of the data inputs selected.

In one embodiment, at least one of the plurality of components has a different size to the others. In another embodiment at least one of the plurality of components has a different tactile property to the others (e.g. rounded edges, sharp edges etc.). This allows a user to distinguish between components. In yet another embodiment, at least one of the plurality of faces of a component has a different tactile property to the others (e.g. smooth, rough etc.). This allows a user to distinguish between faces.

In one embodiment, the data input device is connected to the entity via wired technology. In another embodiment, the data input device is connected to the entity via wireless technology (e.g. Bluetooth).

In one implementation, the data input device is a wearable device. Wearable devices allow computing functionality to be incorporated into a device that a user has on their person. For example, the data input device can be implemented as a piece of digital jewelry e.g. a necklace.

An advantage associated with the present invention is that one face represents one data input at a time and therefore the data input device does not have an associated learning curve, unlike some prior art data input devices (e.g. the chorded keyboard). Furthermore, this ensures that the present invention conforms to the most popular data input devices. Another advantage is that the components can be scaled so that they are easy to manipulate, unlike the keys of some prior art keyboards.

In prior art systems, because of the reduction in size of the data input device and also the inaccuracy of some data input mechanisms (e.g. handwriting recognition), the user is required to inspect the entity during data input. However, the intuitive data input mechanism of the present invention and the tactile feedback provided to the user, allows the user to input data with a moderate level of concentration. Advantageously, the present invention provides the ability for data input in an unobtrusive manner.

Another advantage of the invention is that it is portable and compact. Furthermore, no external pointing device is required and the user can select data inputs using a one handed operation.

Yet another advantage is that since the output of the data input device of the present invention is the same as the output of current data input devices, the present invention can be used with current systems, with little change to hardware or software.

The present invention is preferably embodied as a computer program product for use with a computer system. Such an implementation may comprise a series of computer readable instructions either fixed on a tangible medium, such as a computer readable media, e.g., diskette, CD-ROM, ROM, or hard disk, or transmittable to a computer system, via a modem or other interface device, over either a tangible medium, including but not limited to optical or analog communications lines, or intangibly using wireless techniques, including but not limited to microwave, infrared or other transmission techniques. The series of computer readable instructions embodies all or part of the functionality previously described herein.

Those skilled in the art will appreciate that such computer readable instructions can be written in a number of programming languages for use with many computer architectures or operating systems. Further, such instructions may be stored using any memory technology, present or future, including but not limited to, semiconductor, magnetic, or optical, or transmitted using any communications technology, present or future, including but not limited to optical, infrared, or microwave. It is contemplated that such a computer program product may be distributed as a removable media with accompanying printed or electronic documentation, e.g., shrink wrapped software, pre-loaded with a computer system, e.g., on a system ROM or fixed disk, or distributed from a server or electronic bulletin board over a network, e.g., the Internet or World Wide Web.

In the drawings and specifications there has been set forth a preferred embodiment of the invention and, although specific terms are used, the description thus given uses terminology in a generic and descriptive sense only and not for purposes of limitation.

What is claimed is:

1. A data input device comprising:
a plurality of inter-connected components, each of which has a plurality of faces, at least one of the plurality of faces representing at least one data input; and
a mechanism which enables selection of the at least one data input.

2. A data input device as claimed in claim 1, wherein the at least one of the plurality of faces comprises an associated surface feature and wherein the mechanism enabling selection comprises a detector which detects depression of the surface feature.

3. A data input device as claimed in claim 1, wherein each of the plurality of components is rotatable about a selection position and the mechanism which enables selection comprises detector which detects when the at least one of the plurality of faces is in the selection position.

4. A data input device as claimed in claim 3, further comprising an element which provides tactile feedback when the at least one of the plurality of faces is in the selection position.

5. A data input device as claimed in claim 3, wherein a time threshold is associated with rotation.

6. A data input device as claimed in claim 1, wherein at least one of the plurality of faces represents one or more modes of operation.

7. A data input device as claimed in claim 1, further comprising an associated display.

8. A data input device as claimed in claim 1, wherein at least one of the plurality of components differs in size to the others of the plurality of components.

9. A data input device as claimed in claim 1, wherein at least one of the plurality of components differs in tactile properties to the others of the plurality of components.

10. A data input device as claimed in claim 1, wherein at least one of the plurality of faces differs in tactile properties to the others of the plurality of faces.

11. A data input device as claimed in claim 1, wherein a first component is inter-connected to a second component via a spacing element.

12. A data input device as claimed in claim 1, further comprising a communications link by which the device communicates with an entity.

13. A data input device as claimed in claim 12, wherein the entity is a pervasive computing device.
